(19) United States
(12) Patent Application Publication
(10) Pub. No.: US 2026/0001756 A1
(43) Pub. Date: Jan. 1, 2026

(54) MICRO-ELECTROMECHANICAL GYROSCOPE WITH IN-PLANE ACTUATION AND PITCH/ROLL SENSING

(71) Applicant: STMicroelectronics International N.V., Geneva (CH)

(72) Inventors: Valentina ZEGA, Porto Sant'elpidio (FM) (IT); Gabriele GATTERE, Castronno (Varese) (IT); Yassine BANANI, Vimercate (MB) (IT); Luca Giuseppe FALORNI, Limbiate (MB) (IT); Manuel RIANI, Como (IT); Paola CARULLI, Milano (IT)

(73) Assignee: STMicroelectronics International N.V., Geneva (CH)

(21) Appl. No.: 19/249,625

(22) Filed: Jun. 25, 2025

(30) Foreign Application Priority Data
Jun. 28, 2024 (IT) 102024000014977

(51) Int. Cl. B81B 3/00; G01C 19/5726

(52) U.S. Cl. CPC B81B 3/0051; G01C 19/5726; B81B 2201/0242; B81B 2203/0172; B81B 2203/0307; B81B 2203/0315; B81B 2203/04; B81B 2203/051; B81B 2203/056

(57) ABSTRACT

A micro-electromechanical gyroscope includes a supporting body and a sensor assembly. The sensor assembly includes a transduction mass, constrained to the supporting body for oscillation along a first driving axis perpendicular to the supporting body and along a sensing axis perpendicular to the first driving axis, driving structures each having an actuator, and a driving mass and motion conversion flexures connecting the driving mass to the transduction mass. The actuator causes the driving mass to oscillate along a second driving axis perpendicular to the first driving axis and the sensing axis. The motion conversion flexures cause movements of the transduction mass along the first driving axis in response to movements of the driving mass along the second driving axis. Sensing structures are mechanically coupled to the transduction mass and have a variable capacitance depending on a position of the transduction mass along the sensing axis.

### PRIORITY CLAIM

This application claims the priority benefit of Italian Application for Patent No. 102024000014977 filed on Jun. 28, 2024, the content of which is hereby incorporated by reference in its entirety to the maximum extent allowable by law.

### TECHNICAL FIELD

This disclosure relates to a micro-electromechanical gyroscope with in-plane actuation and pitch/roll sensing.

### BACKGROUND

As is known, in the micro-electromechanical gyroscope sector, the design of the devices faces increasingly stringent market demands, for example demands regarding the precision of the measurements and the robustness against malfunctions, in particular due to external causes.

In general, in a micro-electromechanical gyroscope, a movable mass elastically connected to a substantially planar supporting body (in general, a semiconductor die) is set to oscillation along a driving direction at a controlled driving frequency. When the supporting body rotates around a rotation axis perpendicular to the driving direction, with an angular velocity, the movable mass undergoes a Coriolis force along a sensing direction perpendicular to both the driving direction and the rotation axis. The Coriolis force is in the form of a signal having a carrier frequency equal to the driving frequency and an amplitude modulated by the angular velocity. The constraints are made so that the movable mass may oscillate in the sensing direction due to the Coriolis force, as well as in the driving direction. A variable capacitive coupling between the movable mass and fixed electrodes on the supporting body allows the displacements of the movable mass due to the Coriolis force to be sensed and therefore the angular velocity to be obtained.

Semiconductor manufacturing techniques allow creation of very effective structures for gyroscopes with an in-plane sensing direction, wherein the driving direction and the sensing direction define a plane parallel to the supporting body. Gyroscopes of this type allow sensing rotations around rotation axes perpendicular to the supporting body (yaw) and high precision and linearity may be achieved, especially because the movable mass translates in a plane and there is a lot of flexibility in designing electrodes for capacitive coupling.

Gyroscopes with an out-of-plane sensing direction are instead used for sensing pitch or roll movements (i.e., movements wherein the rotation axis is parallel to the supporting body). The driving direction and the sensing direction are therefore configured to be one parallel to, and the other perpendicular to, the supporting body. Since it is convenient to exploit in-plane movements for actuation, usually the driving direction is parallel to the supporting body (in-plane) and the sensing direction is perpendicular thereto (out-of-plane).

However, the management of out-of-plane movements has many more constraints, especially as to the capacitive coupling. On the one hand, the motion of out-of-plane sensing structures is more sensitive to technological imperfections (for example, the known “wall angle”), which determine, for pitch and roll sensing gyroscopes, the presence of quadrature components and a resulting performance deterioration. On the other hand, the capacitive coupling may be of the parallel-plate type, with a fixed electrode on the supporting body facing the movable mass, which defines the other electrode. This type of coupling is typically more non-linear, for example, compared to comb finger couplings which may instead be exploited for in-plane movements. Accordingly, the readings are also more affected by non-linearity. Furthermore, there is a risk that the movable mass collapses on the driving electrodes of the supporting body due to the prevalence of electrostatic forces, if the applied driving voltage exceeds a critical threshold.

There is accordingly a need to in the art to provide a micro-electromechanical gyroscope which allows the limitations described to be overcome or at least mitigated.

### SUMMARY

In an embodiment, a micro-electromechanical gyroscope includes a supporting body and at least one sensor assembly, wherein the at least one sensor assembly includes a transduction mass, constrained to the supporting body so as to be able to oscillate along a first driving axis perpendicular to the supporting body and along a sensing axis perpendicular to the first driving axis; driving structures each including an actuator, a driving mass, and motion conversion flexures connecting the driving mass to the transduction mass, wherein the actuator is configured to cause the driving mass to oscillate along a second driving axis perpendicular to the first driving axis and to the sensing axis and wherein the motion conversion flexures are configured so as to cause movements of the transduction mass along the first driving axis in response to movements of the driving mass along the second driving axis; and sensing structures, mechanically coupled to the transduction mass and having a variable capacitance depending on a position of the transduction mass along the sensing axis.

The driving structures may be symmetrical to each other and arranged adjacent to opposite sides of the transduction mass with respect to the sensing axis.

In each driving structure the actuator may be configured to impart to the driving mass an oscillating motion along the second driving axis.

In each driving structure the actuator may include an auxiliary actuation structure, supported by suspension flexures fixed to the supporting body, yielding in a direction of the second driving axis and rigid in a direction of the first driving axis and the sensing axis; and movable actuation electrodes and fixed actuation electrodes in comb finger configuration; wherein the movable actuation electrodes and the fixed actuation electrodes may include flat semiconductor plates parallel to a plane defined by the first driving axis and the second driving axis and wherein the movable actuation electrodes may be anchored to the auxiliary actuation structure and the fixed actuation electrodes may be anchored to the supporting body.

The auxiliary actuation structures may be coupled to the driving masses by connection flexures rigid in the direction of the second driving axis and yielding in the direction of the sensing axis.

A driving voltage may be applied to the driving structures with opposite polarities, causing electrostatic forces in opposite directions, thereby causing oscillations of the auxiliary actuation structures at a driving frequency and in phase opposition.

The sensing structures may be symmetrical to each other and arranged adjacent to opposite sides of the transduction mass with respect to the second driving axis.

Each sensing structure may include an auxiliary sensing structure, supported by suspension flexures yielding in a direction of the sensing axis and rigid in a direction of the first driving axis and the second driving axis; and movable sensing electrodes and fixed sensing electrodes in comb finger configuration; wherein the movable sensing electrodes and the fixed sensing electrodes may include flat semiconductor plates parallel to a plane defined by the first driving axis and the sensing axis and wherein movable sensing electrodes may be anchored to the auxiliary sensing structure and the fixed sensing electrodes may be anchored to the supporting body.

The transduction mass may be coupled to the sensing structures by connection flexures rigid in the direction of the sensing axis and yielding in the direction of the second driving axis.

The motion conversion flexures may be configured to cause translation movements of the transduction mass in a direction of the first driving axis in response to displacements of the driving mass along the second driving axis.

The motion conversion flexures may have an elongated shape in a direction of the sensing axis and each may have a first end anchored to the transduction mass and a second end anchored to the driving mass.

The motion conversion flexures may be of a skew-bending type.

Each motion conversion flexure may include a first elastic body, a second elastic body and a plurality of transversal elements; and wherein, in each motion conversion flexure the first elastic body and the second elastic body may be defined by rectangular flat plates, in rest conditions perpendicular to the second driving axis and elongated in a direction of the sensing axis; and the first elastic body and the second elastic body may be offset with respect to each other in the direction of a first reference axis X and in the direction of a third axis Z of a set of X, Y, and Z Cartesian axes.

The transversal elements may be defined by flat plates in rest conditions perpendicular to the second axis, may be uniformly spaced along the second axis and may have first sides connected to the first elastic body and second sides, opposite to the first sides, connected to the second elastic body.

The micro-electromechanical gyroscope may include a first sensor assembly and a second sensor assembly arranged side by side, identical to each other and having parallel sensing axes, first driving axes and second driving axes, wherein the transduction masses of the first sensor assembly and the second sensor assembly may be coupled to each other by first connection flexures and to the supporting body by second connection flexures, acting in a direction parallel to the sensing axes.

The micro-electromechanical gyroscope may include a control unit and a driving stage, configured to operate the driving structures of the first sensor assembly in phase opposition with respect to the driving structures of the second sensor assembly, so that the transduction mass of the first sensor assembly and the transduction mass of the second sensor assembly oscillate in phase opposition with each other and the sensing structures react differentially to rotations of the supporting body around a rotation axis parallel to the second driving axis.

The motion conversion flexures of each driving structure may be offset to each other along the second driving axis and the transduction mass may include distinct anchors for each motion conversion flexure, wherein the offset arrangement may allow for longer motion conversion flexures.

Each motion conversion flexure may have sections with main axes of inertia that form an angle β with local axes that are parallel to the first driving axis and the second driving axis, wherein the angle β may enable a skew-bending characteristic of the motion conversion flexures.

A skew-bending of the motion conversion flexures may cause, in response to a displacement of a first end of the motion conversion flexure along the first driving axis, a rototranslation of a median section of the motion conversion flexure and a translation of a second end of the motion conversion flexure in a direction of the second driving axis.

Constraints of the transduction mass and the sensing structures may be configured to cause motion of auxiliary sensing structures to occur substantially in a plane defined by the second driving axis and the sensing axis.

In an embodiment, a system for measuring angular rotation may include a micro-electromechanical gyroscope including a transduction mass constrained to oscillate along a first driving axis perpendicular to a supporting body and along a sensing axis perpendicular to the first driving axis; a sensing interface coupled to the micro-electromechanical gyroscope and configured to receive sensing signals from sensing terminals of the micro-electromechanical gyroscope; an analog-to-digital converter coupled to the sensing interface and configured to generate digital sensing signals from amplified reading signals provided by the sensing interface; a control unit coupled to the analog-to-digital converter and configured to process the digital sensing signals to provide an output signal indicative of an angular velocity around the sensing axis; and a driving stage coupled to the control unit and the micro-electromechanical gyroscope, the driving stage controlled by the control unit and configured to provide a driving voltage to keep movable portions of the micro-electromechanical gyroscope in oscillation with a constant driving frequency.

The sensing interface, the analog-to-digital converter, the control unit, and the driving stage may be components of a dedicated integrated circuit coupled to the micro-electromechanical gyroscope.

The driving stage may be configured to apply the driving voltage between movable actuation electrodes and fixed actuation electrodes of the micro-electromechanical gyroscope to set an auxiliary actuation structure to oscillation along a second driving axis at the constant driving frequency.

The micro-electromechanical gyroscope may include first and second sensor assemblies, and wherein the control unit may be configured to operate driving structures of the first sensor assembly in phase opposition with respect to driving structures of the second sensor assembly.

The output signal may be generated by the control unit based on capacitive variations of sensing structures of the micro-electromechanical gyroscope, the capacitive variations occurring in response to displacements of the transduction mass along the sensing axis caused by Coriolis forces acting on the transduction mass when the system rotates around a rotation axis parallel to a second driving axis of the micro-electromechanical gyroscope.

### BRIEF DESCRIPTION OF THE DRAWINGS

For a better understanding, embodiments are presented, by way of non-limiting example, with reference to the attached drawings, wherein:

FIG. 1 is a block diagram of a micro-electromechanical gyroscope;

FIG. 2 is a top-plan view of a microstructure of the gyroscope of FIG. 1;

FIG. 3 is a cross-section of the microstructure of FIG. 2, taken along the line III-III of FIG. 2, in a first operating configuration;

FIG. 4 shows the view of FIG. 3, with the microstructure in a second operating configuration;

FIG. 5 is a cross-section of the microstructure of FIG. 2, taken along the line V-V of FIG. 2, in the first operating configuration;

FIG. 6 shows the view of FIG. 5, with the microstructure in the second operating configuration;

FIG. 7 is a top-plan view of a micro-electromechanical gyroscope;

FIG. 8 is a top-plan view of an enlarged detail of the microstructure of FIG. 2;

FIG. 9 is a partial perspective view of the detail of FIG. 8;

FIGS. 10a-10c are respectively a first, a second and a third cross-section of the detail of FIG. 5 in the first operating configuration; and

FIGS. 11a-11c show the views respectively of FIGS. 10a-10c in the second operating configuration; and

FIG. 12 is a top-plan view of a micro-electromechanical gyroscope.

### DETAILED DESCRIPTION

The following description refers to the arrangement shown in the drawings; consequently, expressions such as “above”, “below”, “upper”, “lower”, “top”, “bottom”, “right”, “left” and the like relate to the attached Figures and are not to be interpreted in a limiting manner.

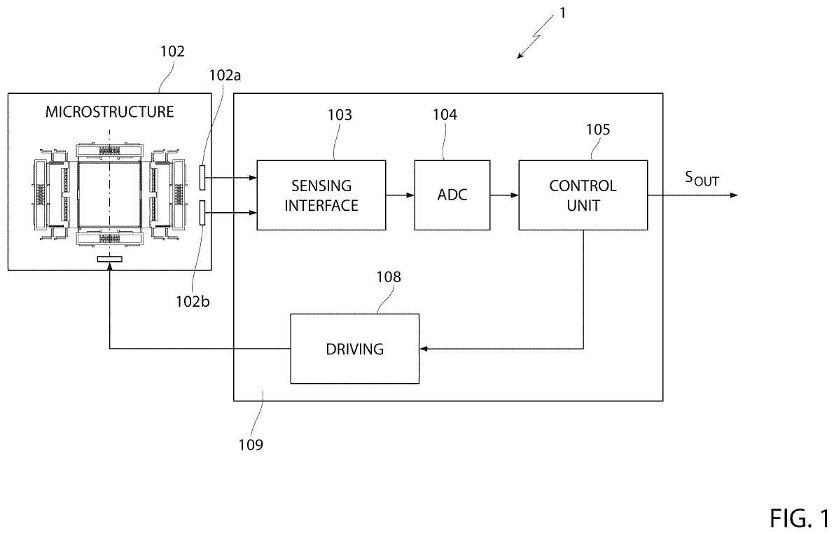

With reference to FIG. 1, a micro-electromechanical gyroscope is indicated as a whole by the reference 1 and comprises a microstructure 102, a sensing interface 103, an analog-to-digital converter 104, a control unit 105 and a driving stage 108. The sensing interface 103, the analog-to-digital converter 104, the control unit 105 and the driving stage 108 may be components of a dedicated integrated circuit or ASIC (Application Specific Integrated Circuit) 109 coupled to the microstructure 102.

The sensing interface 103 receives sensing signals from a first sensing terminal 102a and a second sensing terminal 102b of the microstructure 102, respectively, and provides amplified reading signals, usable by the analog-to-digital converter 104 to generate digital sensing signals.

The control unit 105 processes the digital sensing signals and provides an output signal S_{OUT} indicative of an angular velocity around a sensing axis (not shown), measured through the microstructure 102.

The driving stage 108 is controlled by the control unit 105 and provides a driving voltage V_{D} to keep movable portions of the microstructure 102 in oscillation with a constant driving frequency ω_{D} and close to a resonance frequency of the same microstructure 102.

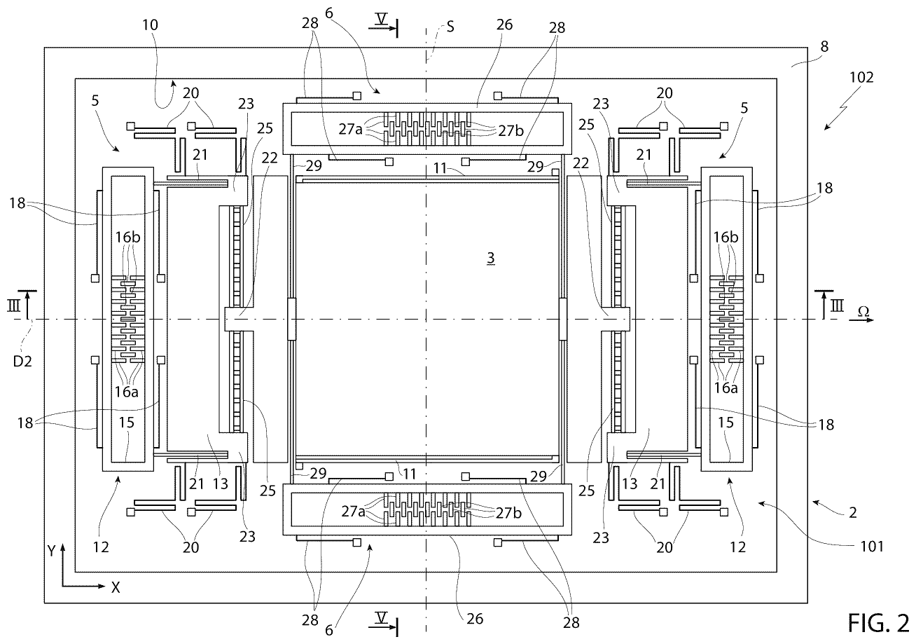

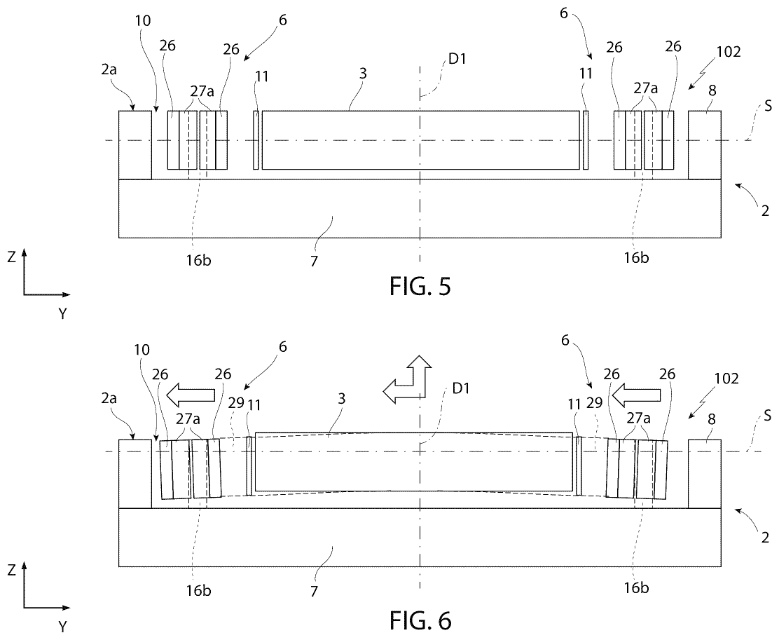

With reference to FIGS. 2-5, the microstructure 102 comprises a supporting body 2 and a sensor assembly 101 in turn including a transduction mass 3, driving structures 5 and sensing structures 6.

The supporting body 2 has a main surface 2a parallel to an XY plane defined by a first reference axis X and a second reference axis Y of a set of three Cartesian axes and perpendicular to a third reference axis Z of the set of three. The supporting body 2 may comprise, for example, a substrate 7 and a frame 8, formed on the substrate 7 and laterally delimiting a cavity 10 where the transduction mass 3, the driving structures 5 and the sensing structures 6 are accommodated. The cavity 10 is also delimited at the bottom by the substrate 7. The substrate 7 and the frame 8 are of semiconductor material, for example respectively monocrystalline and polycrystalline silicon.

The transduction mass 3, also of semiconductor material, is elastically connected to the supporting body 2 so as to be able to oscillate along a first driving axis D1, parallel to the third reference axis Z and perpendicular to the main surface 2a of the supporting body 2, and along a sensing axis S parallel to the second reference axis Y and to the main surface 2a of the supporting body 2. Suspension flexures 11, yielding in the direction of the second reference axis Y and of the third reference axis Z and rigid in the direction of the first reference axis X, couple the transduction mass 3 to the supporting body 2 allowing the desired movements.

The transduction mass 3 is symmetrical with respect to the sensing axis S and to a second driving axis D2, which is parallel to the first reference axis X and perpendicular to the first driving axis D1 and the sensing axis S.

The driving structures 5 are symmetrical to each other and arranged adjacent to respective opposite sides of the transduction mass 3 with respect to the sensing axis S. In detail, each driving structure 5 comprises an actuator 12 and a driving mass 13.

The actuator 12 is configured to impart to the respective driving mass 13 an oscillating motion along the second driving axis D2. In one embodiment, the actuator 12 comprises an auxiliary actuation structure 15, movable actuation electrodes 16a and fixed actuation electrodes 16b. In the example of FIG. 2, the auxiliary actuation structure 15 is a frame having a quadrangular shape and elongated in the direction of the sensing axis S. However, it is understood that this shape is not limiting and the auxiliary actuation structure 15 might be implemented differently, in accordance with design preferences. The auxiliary actuation structure 15 is supported by suspension flexures 18 anchored to the supporting body 2, yielding in the direction of the second driving axis D2 and rigid in the direction of the first driving axis D1 and the sensing axis S.

In one embodiment, the movable actuation electrodes 16a are defined by flat semiconductor plates parallel to an XZ plane, anchored to the auxiliary actuation structure 15 and arranged into two opposite arrays that extend from longer sides of the auxiliary actuation structure 15 towards the inside thereof.

The fixed actuation electrodes 16b are defined by further flat semiconductor plates parallel to the XZ plane and anchored to the substrate 7. The movable actuation electrodes 16a and the fixed actuation electrodes 16b are interdigitated in a comb finger configuration.

In particular, the movable actuation electrodes 16a and the fixed actuation electrodes 16b are shaped and coupled so as to apply, in response to the driving voltage V_{D} provided by the driving stage 108, electrostatic forces oriented according to the second driving axis D2. The driving voltage V_{D} is applied to the driving structures 5 of the two actuators 12 with opposite polarities, so that the electrostatic forces are also opposite, and cause oscillations of the auxiliary actuation structures 15 at the driving frequency ω_{D} and in phase opposition.

The driving stage 108, controlled by the control unit 105, applies the driving voltage V_{D} between the movable actuation electrodes 16a and the fixed actuation electrodes 16b to set the auxiliary actuation structure 15 to oscillation along the second driving axis D2 at the driving frequency ω_{D}.

In each actuator 12, the driving mass 13 is supported by suspension flexures 20 anchored to the supporting body 2, yielding in the direction of the sensing axis S and the second driving axis D2 and rigid in the direction of the first driving axis D1. The shape of the suspension flexures 20 therefore favors the in-plane motion of the driving masses 13.

The driving mass 13 is coupled to the actuators 12 by connection flexures 21 rigid in the direction of the second driving axis D2 and yielding in the direction of the sensing axis S. In this manner, the connection flexures 21 transfer the oscillatory motion along the second driving axis D2 to the driving mass 13 without interfering with the movements along the sensing axis S caused by rotations around a rotation axis coinciding with the second driving axis D2.

The driving mass 13 is also coupled to the transduction mass 3 through motion conversion flexures 25 having skew bending, configured to cause translation movements of the transduction mass 3 in the direction of the first driving axis D1 in response to displacements of the driving masses 13 in phase opposition with each other along the second driving axis D2. Skew bending occurs when the moment applied to the section of a beam does not act along one of the main inertia planes causing a combination of bendings in multiple orthogonal planes. In this case, the inflection plane of the body does not coincide with the stress plane. The skew bending may be considered as composed of two straight bendings acting along the two main inertia planes.

The motion conversion flexures 25 have an elongated shape in the direction of the second reference axis Y and the sensing axis S and connect, in each actuator 12, the respective driving mass 13 to the transduction mass 3. More precisely, the motion conversion flexures 25 have a first end connected to an anchor 22 of the transduction mass 3 and a second end connected to an anchor 23 of the respective driving mass 13. In the embodiment of FIG. 2, the motion conversion flexures 25 of each actuator 12 are symmetrical to each other.

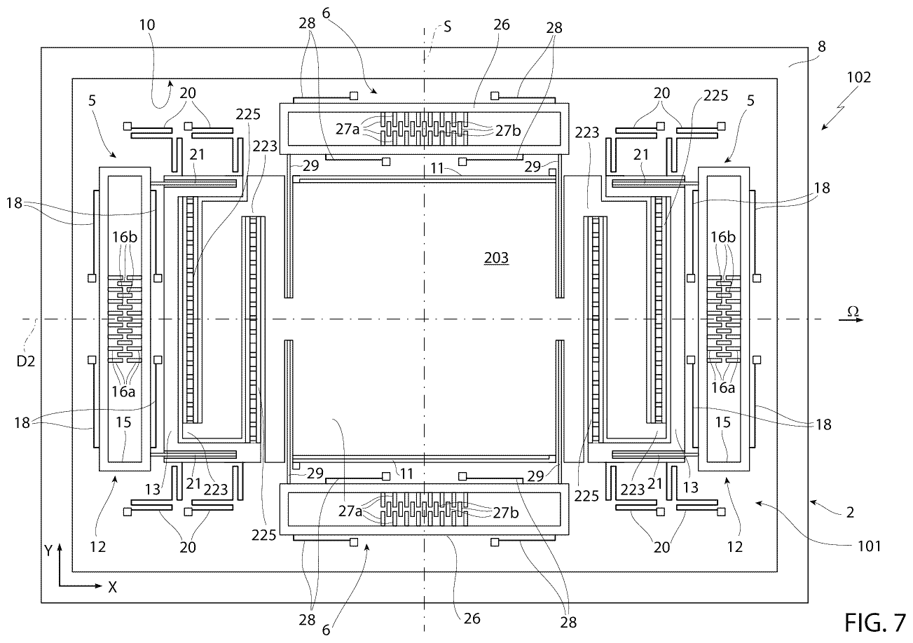

In FIG. 2, in particular, in each actuator 12 the motion conversion flexures 25 are aligned with each other and extend in opposite directions from the anchor 22 of the transduction mass 3 towards the respective anchors 23 of the driving mass 13. The configuration of the motion conversion flexures 25 is however not to be understood as limiting and might be different, based on design preferences. For example, in FIG. 7, the motion conversion flexures, indicated here by 225, are offset to each other along the second driving axis D2 and the transduction mass 203 is provided with distinct anchors 223 for each motion conversion flexure 225. In this manner, longer motion conversion flexures 225 may be exploited.

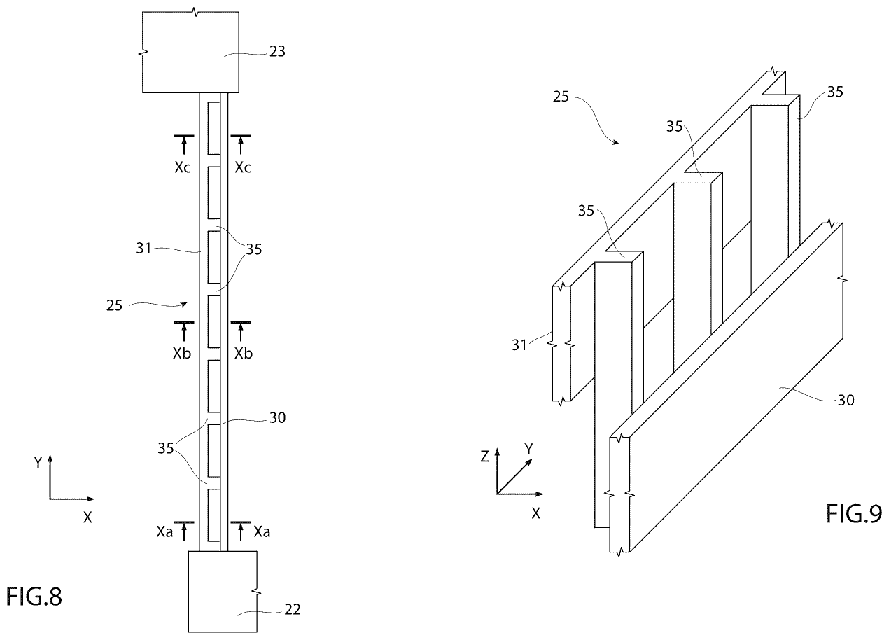

The structure of the motion conversion flexures 25 will be described in detail hereinafter with reference to FIGS. 8, 9, 10a-c, 11a-c.

The sensing structures 6 are symmetrical to each other and arranged adjacent to respective opposite sides of the transduction mass 3 with respect to the second driving axis D2.

Each sensing structure 6 comprises an auxiliary sensing structure 26, movable sensing electrodes 27a and fixed sensing electrodes 27b. In the example of FIG. 2, the auxiliary sensing structure 26 is a frame having a quadrangular shape and elongated in the direction of the second driving axis D2. However, it is understood that this shape is not limiting and the auxiliary sensing structure 26 might be implemented differently, in accordance with design preferences. The auxiliary sensing structure 26 is supported by suspension flexures 28 yielding in the direction of the sensing axis S and rigid in the direction of the first driving axis D1 and the second driving axis D2. In this manner, the auxiliary sensing structures 26 are substantially movable only in-plane along the sensing axis S. In the direction of the first driving axis D1, any deformations of the suspension flexures 28 are limited to what is useful for accommodating the movements of the transduction mass 3.

In one embodiment, the movable sensing electrodes 27a and the fixed sensing electrodes 27b are defined by flat semiconductor plates parallel to a YZ plane, anchored to the auxiliary sensing structure 26 and to the supporting body 2 respectively, and are in finger comb configuration. The movable sensing electrodes 27a and the fixed sensing electrodes 27b are further perpendicular to the movable actuation electrodes 16a and the fixed actuation electrodes 16b of the actuators 12. The capacitance between the movable sensing electrodes 27a and the fixed sensing electrodes 27b depends on the position of the transduction mass 3 and, accordingly, of the auxiliary sensing structures 26 along the sensing axis S.

The transduction mass 3 is coupled to the sensing structures 6 by connection flexures 29 rigid in the direction of the sensing axis S and yielding in the direction of the first driving axis D1 and the second driving axis D2. In one embodiment, the connection flexures 29 are symmetrical with respect to the second driving axis D2.

In this manner, the connection flexures 29 transfer to the auxiliary sensing structures 26 the movements along the sensing axis S caused by rotations around a rotation axis coinciding with the second driving axis D2 without interfering with the oscillatory motion along the first driving axis D1 of the driving mass 13.

With reference also to FIGS. 8 and 9, the motion conversion flexure 25 comprises a first elastic body 30, a second elastic body 31 and a plurality of transversal elements 35, which are formed for example of the same semiconductor material as the substrate 7 and the frame 8 and form a single piece.

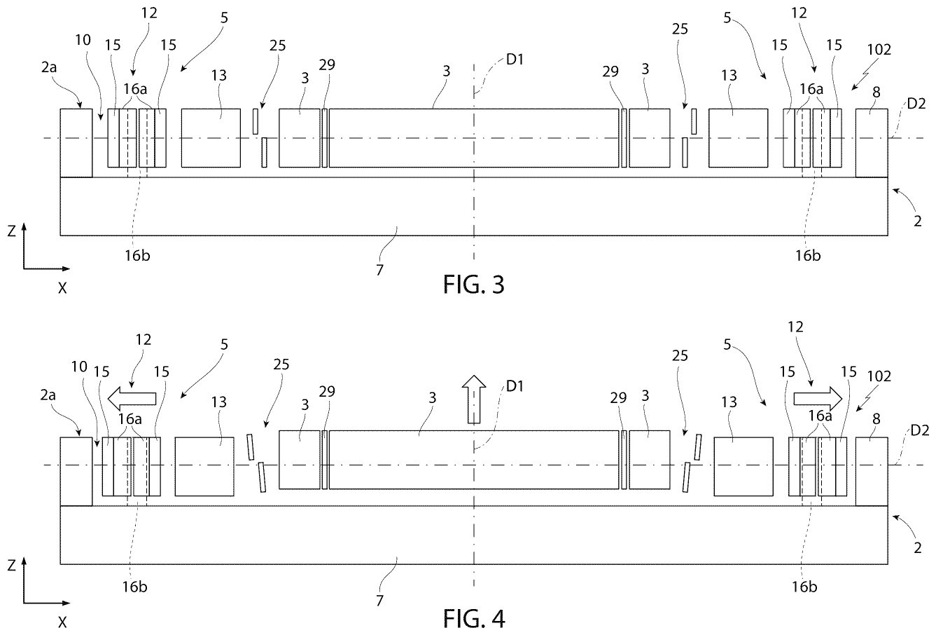

The first elastic body 30 and the second elastic body 31 are defined by rectangular flat plates having the same shape, in rest conditions perpendicular to the first reference axis X and elongated in the direction of the second reference axis Y. The first elastic body 30 and the second elastic body 31 are offset to each other both in the direction of the first reference axis X and in the direction of the third reference axis Z. For example, the first elastic body 30 extends adjacent to the transduction mass 3 and at a greater distance from the respective driving mass 13; vice versa, the second elastic body 31 extends adjacent to the respective driving mass 13 and at a greater distance from the transduction mass 3. Furthermore, the first elastic body 30 is closer to the substrate 7 than the second elastic body 31 (see also FIG. 3). For example, a lower edge of the first elastic body 30 is aligned, in rest conditions, with a face of the transduction mass 3 arranged facing the substrate 7; an upper edge of the second elastic body 31 is aligned with a face of the driving mass 13 arranged facing outwards. The first elastic body 30 and the second elastic body 31 have a dimension along the third reference axis Z smaller than the transduction mass 3 and the driving mass 13.

The transversal elements 35 are defined by flat plates having the same shape, for example rectangular, in rest conditions perpendicular to the second reference axis Y. The transversal elements 35 are uniformly spaced along the second reference axis Y and have first sides connected to the first elastic body 30 and second sides, opposite to the first sides, connected to the second elastic body 31.

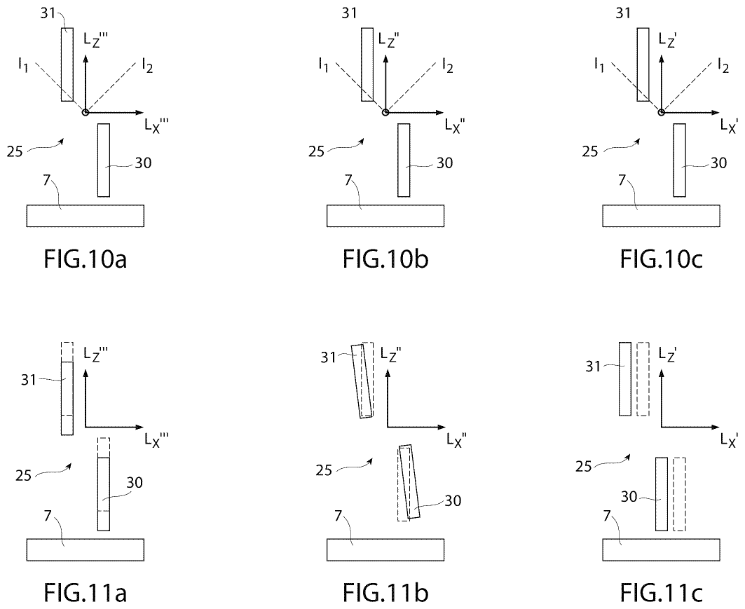

FIGS. 10a-10c show, by way of example, cross-sections of the motion conversion flexure 25 along planes parallel to the XZ plane at the first end, at a median portion and at the second end, respectively. In each of the FIGS. 10a-10c the main axes of inertia I₁, I₂ of the corresponding section of the first motion conversion flexure 25 are also shown, assuming that this section has infinitesimal thickness. In rest conditions, in particular, the main axes of inertia I₁, I₂ have a same orientation in each section and are misaligned and transversal with respect to both the first reference axis X and the third reference axis Z. Furthermore, in FIGS. 10a-10c, in rest conditions, pairs of local axes (indicated respectively by Lx′-Lz′, Lx″-Lz″ and Lx″-Lz″) are also shown, each pair being formed by axes parallel to the first reference axis X and the third reference axis Z, respectively, and passing through the barycenter of the section shown.

For each section of the first motion conversion flexure 25, a centrifugal moment of inertia Ic may be calculated, with respect to the corresponding pair of local axes, through the integral:

$${I}_{C} = \int \int {r}_{1} {r}_{2} dA$$

where r₁ and r₂ represent the distance of each point of the section from a first and a second axis of the pair of local axes, respectively, while dA is the area unit of the section. The centrifugal moment of inertia Ic is non-zero, since the local axes are not axes of symmetry of the section and therefore do not coincide with the main axes of inertia I₁, I₂. In particular, the main axes of inertia I₁, I₂ form an angle β with the local axis parallel to the third reference axis Z and with the local axis parallel to the first reference axis X, respectively.

Accordingly, as can be seen in FIGS. 11a-11c, a force applied on the motion conversion flexure 25, for example along the local axis Lz″, causes a skew bending of the motion conversion flexure 25. In particular, this force causes a deformation along the local axis Lz″, which entails a resulting deformation along the local axis Lx″. Compared to the rest positions, represented with a dashed line, in response to a displacement of the first end of the motion conversion flexure 25 along the third reference axis Z (FIG. 11a) the skew bending causes a rototranslation of the median section (FIG. 11b) and the translation of the second end in the direction of the first reference axis X (FIG. 11c). Due to the skew bending, the motion along the second driving axis D2 imparted by the driving masses 13 to the first ends of the motion conversion flexures 25 due to the driving voltage V_{D} is converted into a corresponding motion along the first driving axis D1 of the second ends of the motion conversion flexures 25 and therefore of the transduction mass 3.

Therefore, the motion conversion flexures 25 convert the driving of the actuators 12 along the second driving axis D2 into a motion of the transduction mass 3 along the first driving axis D1. The constraints represented by the suspension flexures 11, 18, 20, 28 and by the connection flexures 21, 29 accommodate the skew bending of the motion conversion flexures 25 and facilitate the correct movement of the transduction mass 3 and of the sensing structures 6.

In practice, therefore, the driving structures 5 keep the transduction mass 3 in oscillation along the first driving axis D1 with an out-of-plane motion perpendicular to the substrate 7 at the driving frequency ω_{D}. When the microstructure 102 rotates with angular velocity ω around a rotation axis parallel to the second driving axis D2 (pitch movement), due to the oscillation along the first driving axis D1 the transduction mass 3 is subject to a Coriolis force directed along the sensing axis S and oscillating at the driving frequency ω_{D} with amplitude modulated by the angular velocity ω. Since the constraints of the transduction mass 3 also allow translation in the direction of the sensing axis S, the oscillatory motion of the transduction mass 3 in this direction is transmitted to the sensing structures 6. The constraints to which the sensing structures 6 are subject cause the motion of the auxiliary sensing structures 26 to occur substantially in the XY plan. This allows, on the one hand, intrinsically linear sensing structures, such as capacitors with interdigitated electrodes in a comb finger configuration to be used and, on the other hand, the collapse of the sensing electrodes on the substrate 7 to be avoided. Between the transduction mass 3 and the substrate 7 in fact, no capacitive coupling is established and there are no electrostatic forces that may cause collapse. Furthermore, possible effects caused by imperfections of the wall angle, which typically may determine quadrature components and accordingly reduce the performances in out-of-plane type gyroscopes, may be mitigated.

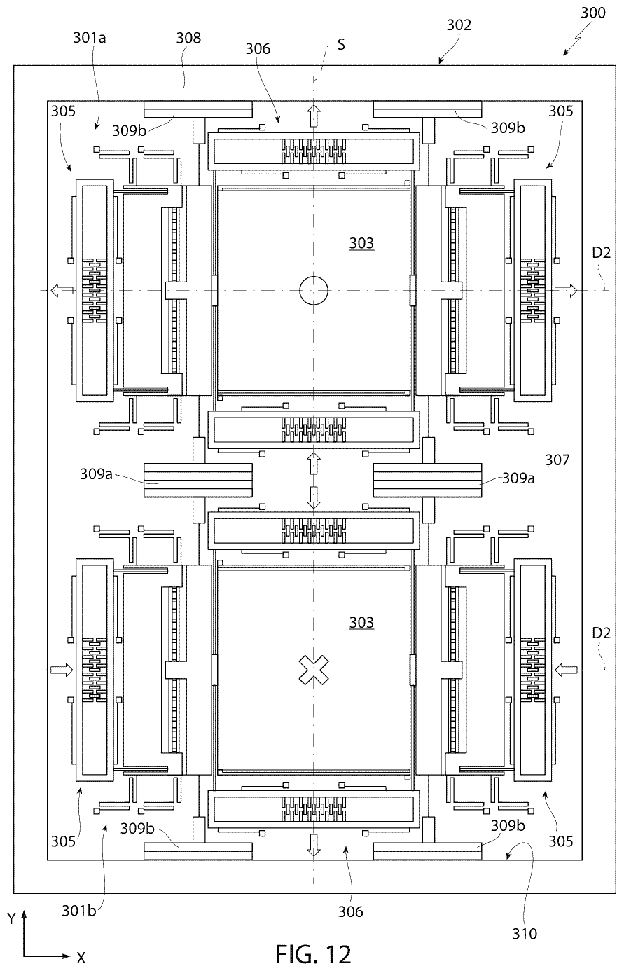

With reference to FIG. 12, a micro-electromechanical gyroscope has a microstructure 300 that comprises a supporting body 302 and two sensor assemblies 301a, 301b arranged side by side, each including a transduction mass 303, driving structures 305, and sensing structures 306. The supporting body 302 is similar to the supporting body 2 of FIGS. 2-6 and comprises a substrate 307 and a frame 308, formed on the substrate 307 and laterally delimiting a cavity 310 where the transduction mass 303, the driving structures 305 and the sensing structures 306 are accommodated. The cavity 310 is also delimited at the bottom by the substrate 307. The substrate 307 and the frame 308 are of semiconductor material, for example respectively monocrystalline and polycrystalline silicon.

The sensor assemblies 301a, 301b are substantially identical to the sensor assembly 101 of FIGS. 2-6, they operate in the same manner and have the respective sensing axes S, parallel first driving axes D1 and second driving axes D2. Each sensor assembly 301a, 301b comprises a transduction mass 303, driving structures 305 and sensing structures 306. Furthermore, the transduction masses 303 of the two sensor assemblies 301a, 301b are coupled to each other by connection flexures 309a of the tuning fork type and to the supporting body 302 by further connection flexures 309b, all acting in a direction parallel to the sensing axis S. Through the driving stage 108, the control unit 105 operates the driving structures 305 of the sensor assembly 301a in phase opposition with respect to the driving structures 305 of the sensor assembly 301b, so that the two transduction masses 303 also oscillate in phase opposition with each other and therefore the respective sensing structures 306 react differentially to the same rotations of the supporting body 302. The connection flexures 309a, 309b favor the differential displacements of the sensing structures 306.

The use of identical sensor assemblies 301a, 301b driven in phase opposition allows a completely differential structure to be formed and the sensitivity of the device to be thus improved.

Finally, it is clear that modifications and variations may be made to the gyroscope described and illustrated herein without thereby departing from the scope of the present invention, as defined in the attached claims.

1. A micro-electromechanical gyroscope, comprising a supporting body and at least one sensor assembly, wherein the at least one sensor assembly includes:
a transduction mass constrained to the supporting body to support oscillation along a first driving axis perpendicular to the supporting body and along a sensing axis perpendicular to the first driving axis;
driving structures, wherein each driving structure comprises an actuator, a driving mass, and motion conversion flexures connecting the driving mass to the transduction mass, wherein the actuator is configured to cause the driving mass to oscillate along a second driving axis perpendicular to the first driving axis and to the sensing axis and wherein the motion conversion flexures are configured so as to cause movements of the transduction mass along the first driving axis in response to movements of the driving mass along the second driving axis; and
sensing structures mechanically coupled to the transduction mass and having a variable capacitance depending on a position of the transduction mass along the sensing axis.

2. The micro-electromechanical gyroscope according to claim 1, wherein the driving structures are symmetrical to each other and arranged adjacent to opposite sides of the transduction mass with respect to the sensing axis.

3. The micro-electromechanical gyroscope according to claim 2, wherein the actuator in each driving structure is configured to impart to the driving mass an oscillating motion along the second driving axis.

4. The micro-electromechanical gyroscope according to claim 2, wherein the actuator in each driving structure comprises:
an auxiliary actuation structure, supported by suspension flexures fixed to the supporting body, that is yielding in a direction of the second driving axis and rigid in a direction of the first driving axis and the sensing axis; and
movable actuation electrodes and fixed actuation electrodes in comb finger configuration;
wherein the movable actuation electrodes and the fixed actuation electrodes comprise flat semiconductor plates parallel to a plane defined by the first driving axis and the second driving axis; and
wherein the movable actuation electrodes are anchored to the auxiliary actuation structure and the fixed actuation electrodes are anchored to the supporting body.

5. The micro-electromechanical gyroscope according to claim 4, wherein the auxiliary actuation structures are coupled to the driving masses by connection flexures rigid in the direction of the second driving axis and yielding in the direction of the sensing axis.

6. The micro-electromechanical gyroscope according to claim 4, wherein a driving voltage applied to the driving structures with opposite polarities causes electrostatic forces in opposite directions, thereby causing oscillations of the auxiliary actuation structures at a driving frequency and in phase opposition.

7. The micro-electromechanical gyroscope according to claim 1, wherein the sensing structures are symmetrical to each other and arranged adjacent to opposite sides of the transduction mass with respect to the second driving axis.

8. The micro-electromechanical gyroscope according to claim 1, wherein each sensing structure comprises:
an auxiliary sensing structure supported by suspension flexures that are yielding in a direction of the sensing axis and rigid in a direction of the first driving axis and the second driving axis; and
movable sensing electrodes and fixed sensing electrodes in comb finger configuration;
wherein the movable sensing electrodes and the fixed sensing electrodes comprise flat semiconductor plates parallel to a plane defined by the first driving axis and the sensing axis; and
wherein movable sensing electrodes are anchored to the auxiliary sensing structure and the fixed sensing electrodes are anchored to the supporting body.

9. The micro-electromechanical gyroscope according to claim 8, wherein the transduction mass is coupled to the sensing structures by connection flexures that are rigid in the direction of the sensing axis and yielding in the direction of the second driving axis.

10. The micro-electromechanical gyroscope according to claim 1, wherein the motion conversion flexures are configured to cause translation movements of the transduction mass in a direction of the first driving axis in response to displacements of the driving mass along the second driving axis.

11. The micro-electromechanical gyroscope according to claim 1, wherein the motion conversion flexures have an elongated shape in a direction of the sensing axis and each motion conversion flexure has a first end anchored to the transduction mass and a second end anchored to the driving mass.

12. The micro-electromechanical gyroscope according to claim 1, wherein the motion conversion flexures are of a skew-bending type.

13. The micro-electromechanical gyroscope according to claim 1, wherein each motion conversion flexure comprises a first elastic body, a second elastic body and a plurality of transversal elements; and
wherein, in each motion conversion flexure:
the first elastic body and the second elastic body are defined by rectangular flat plates, in rest conditions perpendicular to the second driving axis and elongated in a direction of the sensing axis; and
the first elastic body and the second elastic body are offset with respect to each other in the direction of a first reference axis X and in the direction of a third axis Z of a set of X, Y, and Z Cartesian axes.

14. The micro-electromechanical gyroscope according to claim 13, wherein the transversal elements are defined by flat plates in rest conditions perpendicular to the second axis and which are uniformly spaced along the second axis and have first sides connected to the first elastic body and second sides, opposite to the first sides, connected to the second elastic body.

15. The micro-electromechanical gyroscope according to claim 1, comprising a first sensor assembly and a second sensor assembly arranged side by side, identical to each other and having parallel sensing axes, first driving axes and second driving axes, wherein the transduction masses of the first sensor assembly and the second sensor assembly are coupled to each other by first connection flexures and coupled to the supporting body by second connection flexures acting in a direction parallel to the sensing axes.

16. The micro-electromechanical gyroscope according to claim 15, comprising a control unit and a driving stage configured to operate the driving structures of the first sensor assembly in phase opposition with respect to the driving structures of the second sensor assembly, so that the transduction mass of the first sensor assembly and the transduction mass of the second sensor assembly oscillate in phase opposition with each other and the sensing structures react differentially to rotations of the supporting body around a rotation axis parallel to the second driving axis.

17. The micro-electromechanical gyroscope according to claim 1, wherein the motion conversion flexures of each driving structure are offset to each other along the second driving axis and the transduction mass comprises distinct anchors for each motion conversion flexure, wherein the offset arrangement allows for longer motion conversion flexures.

18. The micro-electromechanical gyroscope according to claim 1, wherein each motion conversion flexure has sections with main axes of inertia that form an angle β with local axes that are parallel to the first driving axis and the second driving axis, wherein the angle β enables a skew-bending characteristic of the motion conversion flexures.

19. The micro-electromechanical gyroscope according to claim 1, wherein a skew-bending of the motion conversion flexures causes, in response to a displacement of a first end of the motion conversion flexure along the first driving axis, a rototranslation of a median section of the motion conversion flexure and a translation of a second end of the motion conversion flexure in a direction of the second driving axis.

20. The micro-electromechanical gyroscope according to claim 1, wherein constraints of the transduction mass and the sensing structures are configured to cause motion of auxiliary sensing structures to occur substantially in a plane defined by the second driving axis and the sensing axis.

21. A system for measuring angular rotation, comprising:
a micro-electromechanical gyroscope comprising a transduction mass constrained to oscillate along a first driving axis perpendicular to a supporting body and along a sensing axis perpendicular to the first driving axis;
a sensing interface coupled to the micro-electromechanical gyroscope and configured to receive sensing signals from sensing terminals of the micro-electromechanical gyroscope;
an analog-to-digital converter coupled to the sensing interface and configured to generate digital sensing signals from amplified reading signals provided by the sensing interface;
a control unit coupled to the analog-to-digital converter and configured to process the digital sensing signals to provide an output signal indicative of an angular velocity around the sensing axis; and
a driving stage coupled to the control unit and the micro-electromechanical gyroscope, the driving stage controlled by the control unit and configured to provide a driving voltage to keep movable portions of the micro-electromechanical gyroscope in oscillation with a constant driving frequency.

22. The system according to claim 21, wherein the sensing interface, the analog-to-digital converter, the control unit, and the driving stage are components of a dedicated integrated circuit coupled to the micro-electromechanical gyroscope.

23. The system according to claim 21, wherein the driving stage is configured to apply the driving voltage between movable actuation electrodes and fixed actuation electrodes of the micro-electromechanical gyroscope to set an auxiliary actuation structure to oscillation along a second driving axis at the constant driving frequency.

24. The system according to claim 21, wherein the micro-electromechanical gyroscope comprises first and second sensor assemblies, and wherein the control unit is configured to operate driving structures of the first sensor assembly in phase opposition with respect to driving structures of the second sensor assembly.

25. The system according to claim 21, wherein the output signal is generated by the control unit based on capacitive variations of sensing structures of the micro-electromechanical gyroscope, the capacitive variations occurring in response to displacements of the transduction mass along the sensing axis caused by Coriolis forces acting on the transduction mass when the system rotates around a rotation axis parallel to a second driving axis of the micro-electromechanical gyroscope.
